(19) United States
(12) Patent Application Publication
(10) Pub. No.: US 2013/0068287 A1
(43) Pub. Date: Mar. 21, 2013

(54) Rapid Thermal Activation of Flexible Photovoltaic Cells and Modules

(71) Applicant: Alvin D. Compaan, Holland, OH (US)

(72) Inventor: Alvin D. Compaan, Holland, OH (US)

(73) Assignee: UNIVERSITY OF TOLEDO, Toledo, OH (US)

(21) Appl. No.: 13/697,169

(22) PCT Filed: May 10, 2011
(86) PCT No.: PCT/US11/00814

§ 371 Date: Dec. 5, 2012

Related U.S. Application Data
(60) Provisional application No. 61/333,175, filed on May 10, 2010.

(51) Int. Cl. H01L 31/18; H01L 31/0224; H01L 31/042; H01L 31/06

(52) U.S. Cl. CPC H01L 31/186; H01L 31/06; H01L 31/022441; H01L 31/042
USPC 136/249; 438/62; 438/57; 136/252; 136/256

(57) ABSTRACT

A photovoltaic cell includes a polymer window and at least one active semiconductor layer that is conditioned using a cadmium chloride treatment process. The photovoltaic cell is heated, during the cadmium chloride treatment process by a rapid thermal activation process to maintain polymer transparency. A method of producing a photovoltaic cell using the rapid thermal activation process and an apparatus to conduct rapid thermal activation processing are also disclosed.

### STATEMENT REGARDING FEDERALLY SPONSORED RESEARCH

This invention was not made with U.S. Government support and the U.S. Government has no rights in this invention.

### FIELD OF THE INVENTION

The invention relates generally to photovoltaic cells (PV cells) and methods and apparatus for making the same. More particularly, the invention relates to a method of activating semiconductor layers of a flexible PV cell.

### BACKGROUND OF THE INVENTION

There is no admission that the background art disclosed in this section legally constitutes prior art.

PV cells can be used to convert solar energy into electric current. PV cells can include a substrate layer and two ohmic contacts or electrode layers for passing current to an external electrical circuit. The PV cell also includes an active semiconductor junction, usually comprised of two or three semiconductor layers arranged in series. The two-layer type of semiconductor cell consists of an n-type layer and a p-type layer, and the three-layer type includes an intrinsic (i-type) layer positioned between the n-type layer and the p-type layer for absorption of light radiation. The PV cells operate by having readily excitable electrons that can be energized by solar energy to higher energy levels, thereby creating positively charged holes and negatively charged electrons in various semiconductor layers. The junction between n-type and p-type semiconductor layers (or n-i-p layers) creates an electric field across the junction which separates the electron-hole pairs. The separation of these positive and negative charge carriers creates a current of electricity between the two electrode layers in the PV cell.

PV cells are examples of diode structures where light passes through a front window structure and through a transparent electrode layer to energize an active semiconductor junction. Some PV cells utilize active semiconductor layers made from materials that include Group II and Group VI compounds such as, for example, cadmium sulfide, cadmium telluride, zinc sulfide, and zinc telluride. These active semiconductor layers may also include low levels of impurity atoms (dopants) such as indium, phosphorous, copper, and other elements that may be conducive to promote electron-hole pairs to generate a voltage potential and current flow from the cells.

Cadmium telluride PV cells, for example, are built on glass in a superstrate configuration, which takes advantage of glass's transparency, mechanical rigidity and the opportunity to form the back contact last. However, glass is heavy and its rigidity and fragility are disadvantages for many applications. As an alternative material for superstrates, transparent polymers can be used instead of glass. Polymer materials, however, impose processing limitations because of certain material property changes due to, for example, temperature and chemical exposure. These processing parameters are known to darken or otherwise alter the transparent characteristic of the polymer front window. Such alterations prevent certain wavelengths of the solar spectrum from penetrating to the active layers and thus reduce the overall power efficiency of the PV cell.

For a polycrystalline thin-film PV cell to perform well it is desirable to achieve good passivation of grain boundaries in the layers and at the heterojunction interfaces of the active semiconductor layers. This “passivation” prevents the interfaces of the grain boundary and the defects at the grain boundaries from providing strong pathways for recombination of the photo-excited electrons and holes. If this recombination is too fast, recombination will occur before the electrons and holes are separated to opposite sides of the n-p junction. This, in turn, acts as a short circuit preventing the flow of current and thus limiting or destroying the output of the cell. For the CdS/CdTe heterojunction, grain boundary passivation occurs during a chloride treatment, which involves the annealing of the device in the presence of vapors of CdCl₂. This annealing step may be performed in a partial pressure of Oxygen (often just purified, dry air) and is often called “activation” since the cell performance improves substantially after this process.

The chloride activation treatment also provides other beneficial effects which include inter-diffusion of sulfur and tellurium across the CdS/CdTe interface. This inter-diffusion may yield a graded transition that smoothes any discontinuities due to the approximately 10% difference in the lattice constants between CdS and CdTe. In addition, the chloride treatment improves the quality of the CdTe grains and can lead to a longer minority carrier (hole) lifetime. This improved CdTe grain quality also improves electron transport to the transparent conductive oxide layer and hole transport to the back contact.

The chloride activation step, however, employs one of the highest temperatures in the fabrication process, that may be on the order of 370-400° C. This contrasts with the sputter deposition process, used to form the active layers, which may be performed at 250-300° C. For example, present methods using glass substrates use typically 15 to 30 minutes of treatment due to the heat capacity of the glass and its tendency to fracture when heated or cooled very fast. As previously mentioned, due to the effects of the harsh processing parameters on the polymer materials, it would be desirable to shorten the treatment times needed for these polymer-based cells.

Based on the foregoing background explanation, shorter treatment times would be desirable in order to maintain the transparency and material integrity of polymer substrates and superstrates such as, for example, polyimide superstrates. It would also be advantageous to manufacture a flexible diode such as a PV cell that has a front window with high transparency and low light spectrum absorption and that can be assembled economically and in high volume.

### SUMMARY OF THE INVENTION

In a first aspect, there is provided herein a PV cell that includes a polymer front window layer having an optical transparency characteristic that is not substantially degraded by the process used to form the PV cell. In one embodiment, the PV cell comprises a flexible polymer-based superstrate layer having a first optical transparency characteristic prior to cell layer assembly. At least one active semiconductor layer is applied during cell layer assembly. The semiconductor layer is exposed to a CdCl₂ vapor process and a rapid thermal activation process. The CdCl₂ vapor process, in conjunction with the rapid thermal activation process, permit the polymer-based superstrate layer to take on a second optical transparency characteristic in the wavelength region for CdTe from 400 nm to 900 nm that is 95% of the first optical transparency characteristic.

In a second aspect, there is provided herein a method for rapid activation/passivation of PV cell active semiconductor layers. A rapid thermal activation process utilizes the thin section of a polymer material and its low heat capacity to reduce thermal exposure times and help preserve the polymer's light transparency characteristics.

In a third aspect, there is provided herein an apparatus for producing a PV cell with a polymer front window using a rapid thermal activation process. In one embodiment, the apparatus may include a roll-to-roll process for producing finished or semi-finished PV cells through processing at a plurality of stations.

Various aspects of this invention will become apparent to those skilled in the art from the following detailed description of the preferred embodiment, when read in light of the accompanying drawings.

### BRIEF DESCRIPTION OF THE DRAWINGS

FIG. 1 is a schematic illustration of a process for making a PV cell that can be used for implementing certain embodiments of the invention.

FIG. 2 is a schematic illustration of another process for making a PV cell that can be used for implementing certain embodiments of the invention.

FIG. 3 is a schematic illustration of a portion of a process for making a PV cell that can be used for implementing certain embodiments of the invention.

FIG. 4 is a schematic illustration of an embodiment of a rapid thermal activation process step of the invention.

FIG. 5 is a schematic illustration of a portion of a PV cell showing an embodiment of an electron flow path.

FIG. 6 is a graphical comparison of optical transmissibility of a PV cell before and after a rapid thermal activation processing.

### DETAILED DESCRIPTION OF THE INVENTION

PV cells rely on a substantially transparent or translucent front window layer to admit solar radiation and to provide protection for the underlying cell layers. Described herein is an improvement over PV cells that rely on glass as the transparent front window material. Also described herein is an improved method of fabricating a PV cell having a transparent or translucent polymer front window.

Polymer materials are used as an alternative medium to glass for substrate or superstrate components in constructing PV cells. While certain polymer materials may be less transparent (e.g., some having poor light transmission characteristics in the blue and green wavelengths (about 400 nm to about 550 nm), certain polymer materials have greater flexibility and reduced weight than glass materials. In particular, polymer films, such as polyimide films, can be made sufficiently thin which improves the optical transmissibility of light to the PV cell active layers and which reduces material cost.

There is provided herein a PV cell that is fabricated on a transparent polymer superstrate. In certain embodiments, the PV cell can be fabricated using a magnetron sputter deposition process to form the semiconductor layers. Improvements to the performance of certain layers, some of which are deposited by magnetron sputtering onto polyimide superstrates or substrates, may be realized over those described in U.S. Pat. No. 7,141,863 to Compaan et al. entitled “Method of Making Diode Structures,” the disclosure of which is incorporated herein by reference in its entirety. These improvements relate to processing techniques to assemble and activate the stack arrangement, or specific layer composition and orientation, that has been developed beyond the disclosure of '863 patent, as described herein.

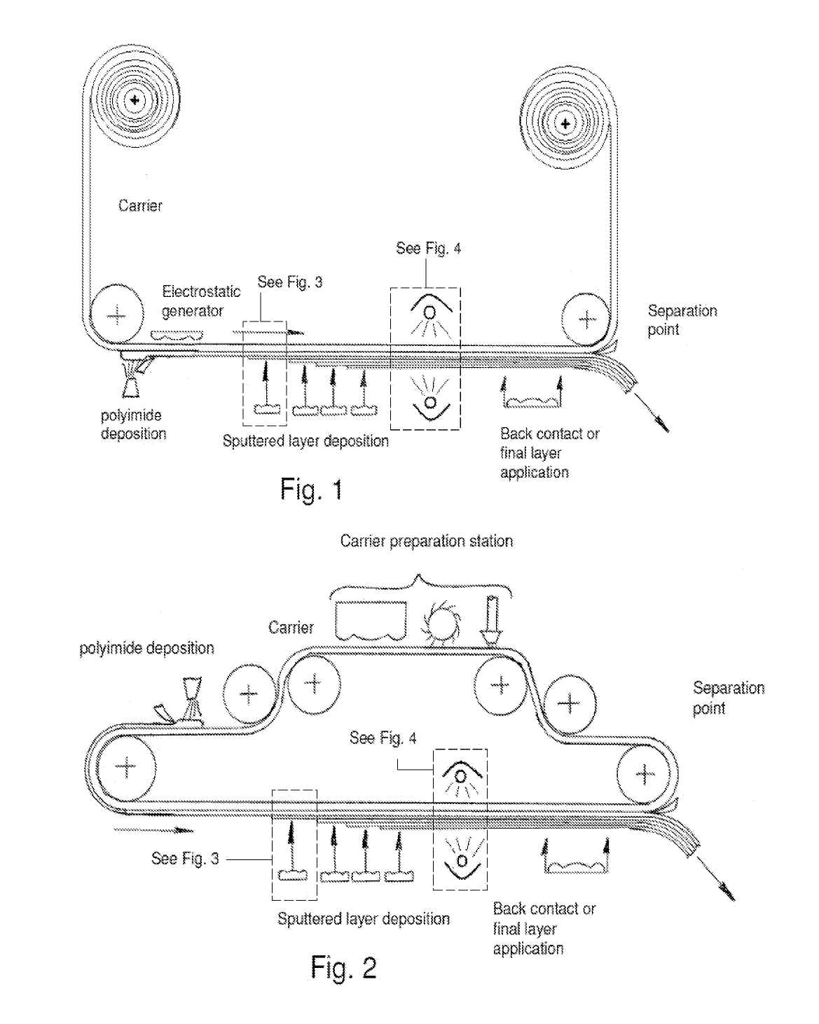

Referring now to FIG. 1, there is depicted a schematic illustration of an apparatus 10 useful for carrying out a method for producing PV cells 12. It is to be understood that FIG. 1 is being shown for illustrative purposes and that other steps and/or processes can be practiced with the inventive method described herein. For instance, various roll-to-roll (RTR) manufacturing processes are used to illustrate the method of the invention. It is to be understood that the various embodiments of the activation method and other processing techniques described herein may be applicable to processing of single PV cells and single PV cell array manufacturing techniques. Thus, the disclosure is not limited to the specific embodiments of the manufacturing processes described herein.

FIG. 1 illustrates a batch run RTR process where a carrier 14 is supplied on a pay-out spool 15. In one embodiment, the method includes the use of an RTR manufacturing process wherein coiled materials may be supplied on spools and drawn into the process equipment by handling machinery. The handling machines may push, pull, or compress the coiled material in order to transfer it to subsequent processing stations. The coiled materials that make up the carrier 14 need to have sufficient strength and flexibility to resist damage from the handling process.

The carrier 14 is a generally thin, flexible material that is capable of supporting various PV cell layers through the various process stations as the PV cell is being constructed, as will be further described herein in detail.

In the embodiment shown in FIG. 1, the carrier 14 is fed into the apparatus 10 where a polymer material 20 is applied onto an outer surface 18 of the carrier 14. The polymer material 20 can be applied by various suitable processes, some of which are described herein.

The carrier layer 14 acts as a fixture to transfer the applied polymer 20 through the manufacturing process. The carrier layer 14 is configured to withstand the various loads imparted by the manufacturing processes used to form the PV cell. The carrier layer 14, however, may be any material having sufficient strength, flexibility, thermal properties (i.e., melting point and thermal expansion), and dimensional stability (i.e., strain and thermal expansion rate) to support the polymer throughout the subsequent cell manufacturing processes. In one embodiment, the carrier layer 14 is a stainless steel foil or sheet material. Alternatively, the carrier layer 14 may be made from metallic or non-metallic sheets such as, for example, copper, aluminum, resin-impregnated carbon fiber or fiberglass sheet materials, or other high temperature polymers.

The polymer material has desired light transmission characteristics, along with desired flexibility and flexural strain characteristics. In certain embodiments, the polymer material comprises a polyimide material. One example of a suitable polymer is a set of polyimide materials sold under the trademark Kapton®.

In certain embodiments, the outer surface 18 of the carrier layer 14 can be prepared for the application of the polymer material 20. For example, the outer surface 18 can be cleaned (for example, by ultrasonic cleaning) and coated, if desired, with a retention coating or a release agent. The polymer material 20 is then applied to the surface 18 of the carrier layer 14 to form a polymer-carrier laminate 22.

Alternatively, the carrier layer 14 may be supplied to the apparatus 10 with the polymer material 20 (and, optionally, any other coatings or release agents) already formed as a sub-assembly in an offline process. As the polymer-carrier laminate 22 is moved through various processing stations 40, 50, 60, 70 of the apparatus 10, the PV cell 12 is formed on the polymer material 20 comprising the polymer-carrier laminate 22.

After a desired number of processing steps are completed, such that at least a semi-finished PV cell 30 is formed on the polymer-carrier laminate 22, the carrier 14 is separated from the polymer-carrier laminate 22. The polymer 20 of the polymer-carrier laminate 22 remains with the semi-finished PV cell 30 such that a mostly-finished PV cell is formed.

As schematically illustrated in FIG. 1, in certain embodiments, once the carrier 14 is separated from the polymer-carrier laminate 22, the carrier 14 can be recoiled on a take-up spool for recycling and/or reprocessing. Alternatively, the unseparated laminate can be recoiled on a take-up spool and later separated off-line.

FIG. 2 illustrates a continuous belt, RTR process 100 where a carrier 114, similar to the carrier 14 described above, forms a continuous loop. The polymer material 120 may be cast onto the carrier 114, either with or against the force of gravity, or may be applied as a separate sheet material, thus forming a polymer-carrier laminate 122. After the semi-finished PV cell 130 is formed on the polymer-carrier laminate 122, the carrier 114 is separated from the polymer 120 of the polymer-carrier laminate 122. The carrier 114 may be moved to a cleaning and preparation station to ready portions of the carrier 114 for subsequent application of the polymer material 120, such as the polyimide material.

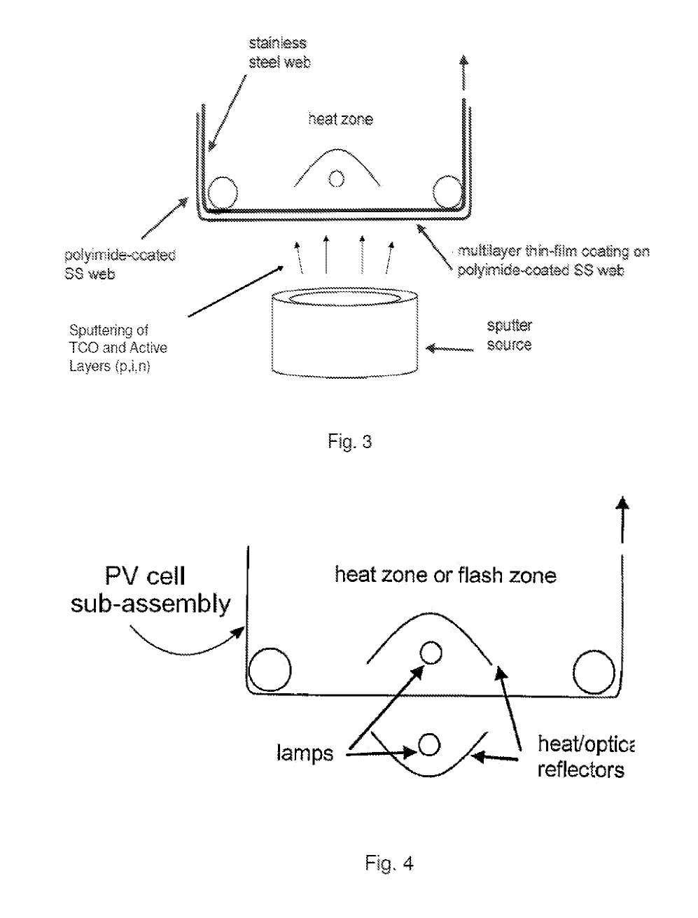

FIG. 3 is a schematic view of a processing station in the RTR manufacturing process for constructing a PV cell. In one embodiment, the processing station uses a sputtering process to build up conductive (i.e., a transparent conductive oxide layer or front contact) and active layers (i.e. p, i, and n layers) of the PV cell. The sputtering process may be, for example, an RF magnetron sputtering process, and other processing stations may include processes such as active layer doping, elevated temperature CdCl₂ annealing, laser scribing, back contact application, and encapsulation.

FIG. 4 schematically illustrates a portion of a CdCl₂ treatment station 200, in accordance with an embodiment of the PV cell fabrication method described herein. The CdCl₂ treatment station 200 includes a heat source 220 and may also include heat shields, heat deflectors, or heat concentrators, shown generally at 240, though such additional thermal and/or optical enhancement devices are not required.

High efficiency cadmium telluride cells and modules may be exposed to a treatment or “activation” with vapors of chlorine. The CdCl₂ treatment station 200 provides a very fast activation process, known as rapid thermal annealing or activation (RTA), which is particularly suited to CdTe-based cells. The CdCl₂ may be applied to the CdTe surface prior to the RTA process or a CdCl₂ vapor may be supplied during the RTA process. In one embodiment of the fabrication method, the CdTe-based cells are fabricated on flexible substrates, which may be either metal foil or polymer sheet that may be readily implemented in a RTR production system. Polymer (or metal foil) substrates/superstrates allow a new approach to the typical chloride activation step in the fabrication of high efficiency CdTe-based PV cells. This RTA process uses rapidly deployable heat sources, such as for example lamp heating, infrared heating, or flashlamp exposure. These rapidly deployable heat sources are capable of providing rapid temperature spikes and may further provide rapid cooling sequences.

The embodiments of the RTA process described herein may not be generally conducive to glass substrates and superstrates because of the rapid heat-up and cool-down rates. Such rapid temperature changes may create thermal shocks that can shatter traditional glass materials, such as soda lime glass. The RTA process described herein, however, works well on metal foil and polymer structures, such as foils, films, or webs, because these materials are very thin (typically 10 to 100 microns) and have low heat capacity. The temperature is generally uniform through the thickness of the foil, plus any coatings, and can be ramped up and down quickly.

The RTA process includes other advantages when applied to polymer substrates and superstrates by permitting processing to reach higher temperatures for short times (i.e., 1-5 minutes). Limiting the exposure time at temperature results in less degradation of the polymer material. By comparison, for glass-based cells and modules, typical processing parameters provide exposures at lower temperature but for longer treatment times (i.e., 15-30 minutes).

The CdCl₂ may be applied to the film structure by spraying with a solution of CdCl₂ in methanol, water or other solvent. The CdCl₂ vapors (including Cd and Cl₂) alternatively may be supplied with a carrier gas such as dry air or mixtures of O₂ and inert gases such as N₂, He, or Ar. Alternatively the Cl may be supplied with Cl-containing molecules such as trichloromethane (chloroform/CHCl₃).

As shown in FIGS. 1 and 2, the RTA process used in the CdCl₂ treatment station 200 can be accomplished on an RTR production line as the PV cell sub-assembly passes through a narrow heat zone 250. A larger heated zone can be created using pulsed flashlamps or heat lamps that are rapidly cycled on and off, if so desired. The heat sources may also include infrared heating elements, microwave generated heating, or magnetic pulse heating using the stainless steel carrier as a heat conductor. The heat zone 250 may concentrate heat using one or more heat/optical reflectors.

The CdCl₂ treatment station 200 includes a chloride treatment process within or adjacent to the heat zone 250 and comprises a chlorine vapor bath, where the vapors may be CdCl₂ vapors. The active layers of the PV cell are exposed to heat and the CdCl₂ vapor for a sufficient time, at the desired temperature, to activate the interfaces and grain boundaries.

Referring again to FIGS. 1 and 2, at one end of the manufacturing line, the polymer 20 is first cast or otherwise applied onto the carrier layer 14. The polymer casting process is generally characterized by application of the polymer in a fluidic state, such as a liquid or a thixotropic paste, onto the carrier. For example, referring again to FIG. 1, a knife edge 16 can be used to evenly distribute the polymer material 20 over the surface 18 of the carrier 14. In one embodiment, the knife edge 16 may be a physical blade or roller device that is spaced apart from the surface of the carrier. In another embodiment, the knife edge 16 may be a fluid stream (such as, for example heated air) that is directed across the surface of the polymer material. The knife edge 16 is subsequently drawn (in a squeegee-like manner), moved, or directed over the polymer material to create a thin film of material. The polymer material 20 may be applied to the surface 18 of the carrier 14 by other suitable processes, such as, but not limited to, spraying, co-extruding, or as co-linear sheets of material that are attached together as the materials are payed out.

Once the polymer material is cast onto the carrier layer, various layers of the thin-film PV cell are applied onto the polymer surface of the polymer-carrier laminate 22. In certain embodiments, specific layers of the PV cell may be applied by any suitable process such as, for example, by sputtering to apply the active n- and p-layers, or collinear extrusion for applying the back contact. For example, referring again to the embodiment of the method illustrated in FIG. 3, the sputtering source applies certain layers of the PV cell, such as the active layers, against the force of gravity. Such an orientation permits the polymer surface to remain free of dust and other contamination that may fall onto the surfaces prepared for sputtering. Alternatively, the sputtering process may be conducted in the direction of the force of gravity or at an angle relative thereto if desired. The process of forming the various active PV layers may be any suitable process.

As the carrier 14 is moved to the various processing stations, the PV cell, or an array of PV cells, may be constructed by being deposited onto the polymer material of the polymer-carrier laminate. In one example, at a first station 40 a transparent conductive oxide (TCO) layer forms the front electrical contact and is configured to allow light to pass through to the active layers below to release electrons, thus creating a voltage and current flow. In one embodiment, the PV cells may be fabricated using sputtered zinc oxide doped with aluminum (ZnO:Al) as the TCO layer. Other materials may be used in the TCO layer such as, for example, indium tin oxide, cadmium tin oxide, and tin oxide doped with F, Sb, or other elements.

In certain embodiments of a second processing station, shown generally at 50, a highly resistive transparent (HRT) layer may be applied between the TCO and the first active layer to form a bilayer. The HRT layer can be made of an undoped ZnO material or Al₂O₃ material, or ZnO:Al material partially oxidized to provide both an electrical isolation function and a chemical diffusion barrier function. For example, in one embodiment, the TCO/HRT bilayer may use a ZnO:Al/ZnO bilayer where the ZnO:Al portion functions as the TCO layer and the undoped portion of ZnO functions as the HRT layer. Other HRT materials are also known.

Next, active layers of CdTe and CdS, for example, are deposited onto the TCO to form the p-type and n-type layers. These steps may be illustrated in the RTR fabrication process as part of process station 60. The CdS and CdTe layers may also be deposited through the sputtering process. An intrinsic, or i-type, layer may be deposited between the n- and p-layers. Additionally, multiple sputtering stations can be positioned to create multiple layered or tandem PV cells.

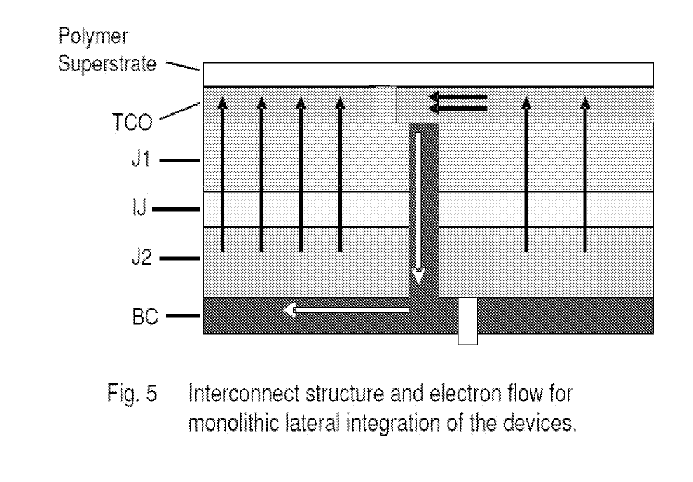

Other processes and/or fabrication steps may be interposed at appropriate points along the manufacturing line to form the various PV layers. Examples of such steps include: (i) doping of the CdTe layer with a suitable dopant, such as for example copper, (ii) a CdCl₂ treatment, as described previously, may be performed at approximately 390° C. for a time that ranges from 5 to 30 minutes, depending on the thickness of the CdTe layer, and (iii) a back contact treatment process involving deposition of a 5-50 \acute{Å} Cu layer followed by 100 nm-200 nm of gold or molybdenum followed by a 5-30 minute anneal at 150° C. for inter-diffusion of the Cu, the processing parameters of which may also depend on the CdTe thickness. Other back contact materials are possible. These process steps are provided as illustrative examples and are not intended to be an exhaustive list of PV cell process steps. Additionally, stations may be positioned at appropriate points along the line for scribing various layers of the PV cell and applying the back contact, if desired. The scribing process may also be interposed between the various sputtering stations to create series or parallel electrical connections for tandem cell construction, similar to the cell of FIG. 5.

An encapsulant can be applied to the semi-finished PV cell to protect the PV cell from damage and exposure to weather and the elements. The encapsulant may be any suitable material to seal the PV cell. Non-limiting examples of suitable encapsulant materials include resins, sealants, plastics and/or polymers such as, for example, polyvinyl chloride, vinyl ester resin, urethane, and phenolic resins. While the encapsulant may be applied as the semi-finished PV cell is still attached to the carrier, it is to be understood that, in certain embodiments, the encapsulation process may be conducted after the PV cell is removed from the carrier. Alternatively, the encapsulation and/or back contact may also be applied in an offline process.

As the assembly of the active layers of the PV cells is completed, the semi-finished PV cell is removed from the carrier. As shown in FIG. 1 and FIG. 2, a separation station or separation point is positioned at or near the end of the RTR manufacturing line. The separation station removes the finished, or semi-finished, PV cell from the carrier.

Referring again to FIG. 1 and FIG. 2, in certain embodiments, the polymer material may be retained onto the carrier by an electrostatic charge applied to the carrier. An electrostatic generator may be positioned proximate the carrier to induce a charge potential on the carrier layer. A downstream electrostatic absorber (not shown) may nullify or otherwise eliminate the charge in order to release the assembled PV cell from the carrier layer.

In a non-limiting example of a structure of the PV cell, as shown in FIG. 5, a polymer layer, such as a polyimide film layer, forms a front window layer. The polyimide film layer is shown oriented as a front window or first layer of the PV cell. In an alternative embodiment of the PV cell, the polymer layer is an electrically conductive polymer layer or a metal layer that forms part of a back contact of the PV cell.

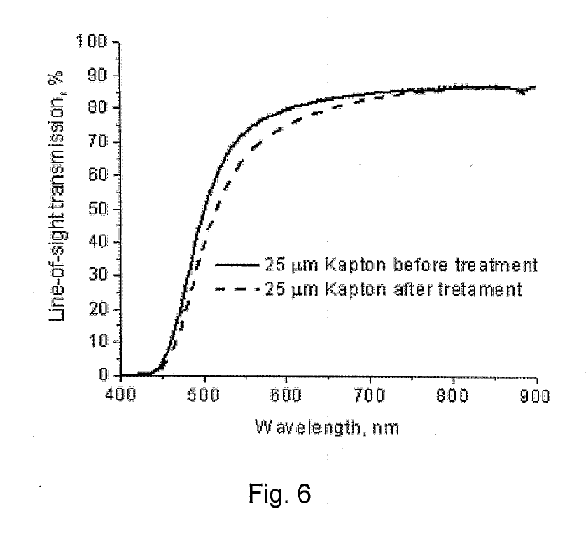

Referring now to FIG. 6, there is illustrated a comparative graph showing the optical transmissibility of Kapton before and after CdCl₂ treatment processing. As shown by the graph, a first optical transparency characteristic is illustrated by the solid line and a second optical transparency characteristic is shown by the dashed line. The difference between the solid and dashed lines represents loss of transparency for a given light wavelength spectrum after processing.

### Examples

The active semiconductor coatings that form the heterojunction CdS/CdTe show improved performance characteristics when the back contact is formed last. The overall PV cell structure is assembled as a superstrate configuration. That is, the PV cells or modules are turned upside down in operation so that sunlight enters through the substrate which is transparent.

While the traditional choice of a superstrate material for the window layer is glass and since the active coatings that form the active PV cell are usually deposited at temperatures of about 550° C. to about 650° C., the coatings may be deposited at much lower temperatures on transparent polymer material, than on glass.

In contrast, the polymer-based window layer described herein provides a light-weight and flexible PV cell. In addition, the low weight and flexibility of such PV cells can provide a variety of advantages over the rigid and heavy glass-based modules, while still retaining the performance of the polycrystalline CdS/CdTe PV junction.

Also, a separable polymer-carrier laminate structure (“laminate”) provides a practical solution for implementing high volume PV cell production.

In one embodiment, the laminate is comprised of a thin metal foil carrier and a polyimide polymer layer that are detachably adhered, or laminated, together. The laminate may have releasable characteristics that allow the metal foil carrier to be removed from the polyimide polymer layer after most of the fabrication of the PV module is completed.

The use of the polymer-carrier laminate allows for the deposition of PV film layers on large-area polyimide films since the manufacturing of flexible CdTe-based modules can be attainable while the polyimide window layer is still attached to the flexible metal carrier.

The removal of the metal foil carrier provides a PV cell structure that can be semitransparent, if a suitably transparent back contact is used. Combined with the excellent thickness control available through magnetron sputtering, this allows for the production of PV cells that can use much of the available light but still be sufficiently light transmissive for architectural use.

Semi-Transparent PV Module

In one example, a semitransparent PV module can include an electrically conductive and transparent back contact of the CdTe PV cell. In such an embodiment, the polyimide superstrate and the front contact are also transparent, thus permitting some light to pass through the PV cell to the active layers, such as the CdTe and CdS layers.

The use of the carrier-polymer laminate allows for the production of a very thin layer of polymer which, in turn, allows for the light transmissiveness of the PV cell. In certain embodiments, PV cells can be fabricated with CdTe layers having a thickness of only about 0.5 μm that still can operate with 10% efficiency and still transmit about 5% of the light through the entire structure. In other embodiments, PV cells thinner than about 0.5 μm can transmit more light at some sacrifice of efficiency.

Monolithic Integrated Modules

The polymer-carrier laminate and the processes described herein also provide: 1) improvements to the robustness of manufacturing of CdTe-based PV modules through the use of a metal foil/polymer laminate structure in an RTR process that allows the metal to be removed before module encapsulation; 2) a semitransparent module for window applications; and 3) an RTR production line for light-weight and flexible CdTe-based PV cell modules.

In one method of the present invention, an RTR manufacturing process uses a polyimide layer releasably attached (i.e., temporarily adhered) to a metal foil to provide an improvement to the fabricating process of a TCO/CdS/CdTe/(back contact) cell structure. In certain embodiments, a very long (>1 km) and wide (˜1 m) laminate can be used to facilitate the high volume production in the RTR process.

In one embodiment, the PV cell sub-modules, while attached to the polymer-carrier laminate, are monolithically integrated by using a laser scribing and ink jet backfill process. Such methods can also produce a semi-transparent PV cell array suitable for window applications.

Handling of Polyimide Materials using Metal Carrier

In another embodiment, there is described herein an improved method for handling of the polyimide material during processing. The processing steps include: 1) a heating step, in a vacuum, to a deposition temperature of about 250° C. followed by the sputter deposition of ZnO:Al, CdS, and CdTe layers; then 2) an activation treatment at about 390° C. in dry air with saturated vapors of CdCl₂; followed by 3) a vacuum deposition of the metal back contact; and, 4) a final heat treatment near 150° C. in air to achieve good ohmic contact.

In certain embodiments, the method may further include one or more appropriate interlayer coatings that are applied to the metal carrier. During the PV cell fabrication process, the interlayer coating may be applied between the metal carrier and polyimide material. The interlayer coating can act both as a temporary adherent and as a release agent to facilitate removal of the polyimide layer (and the built-up PV cell structure thereon) from the metal carrier without damaging the flexible PV cell structure.

Also, in certain embodiments, the delaminated coated metal foil carrier is sufficiently undamaged by the delamination step so as to be recycled and reused in further cycles of the manufacturing process of the PV cells.

The metal foil carrier can be configured to be compatible with the pay-out, transport, and take-up systems needed for an RTR manufacturing line. In one embodiment, the metal foil material may be a stainless steel laminate foil material.

Example of Fabrication Sequence

The polymer-carrier laminate (comprised of a polyimide film applied to a stainless steel metal foil) supports the steps in the fabrication sequence of CdS/CdTe PV modules. These steps can include: 1) the deposition at ˜250° C. of a TCO layer on the polyimide (in one embodiment the TCO layer is ZnO:Al); 2) deposition of an HRT layer; 3) the deposition at ˜250° C. of the active semiconductor layers of CdS and CdTe; 4) an activation step usually involving a temperature near 390° C. in the presence of CdCl₂, and finally 5) application of a back contact through a metallization process.

Following this sequence of cell fabrication steps, the metal lamination layer is removed from the polyimide film without damaging the polyimide or the PV-cell layers. Thus, the fabrication of the complete PV cell sub-module includes the deposition of all the PV cell layers (e.g., TCO/HRT/CdS/CdTe/back contact) and the cadmium chloride activation step.

Efficiency in Use of CdTe Materials

The PV cell structure (and methods used to produce such PV cells described herein) can facilitate the reduction in the thickness of the CdTe layer, while still maintaining the desired high efficiencies of the PV cell.

Additional benefits include: a reduction of the manufacturing line length, a reduction of CdCl₂ activation time, and a reduction in the amounts of cadmium and tellurium needed.

Efficiencies in Encapsulation

In another embodiment, the process of encapsulation can include steps such as “edge deletion,” forming buss lines, bypass diodes, and junction boxes, together with a robust module encapsulation process. These steps are compatible with the polymer-carrier lamination process described herein.

By encapsulating the PV cell sub-module using the polymer-carrier laminate process described herein, the manufacturing process yields complete PV modules that exhibit long-term solar exposure endurance, as well as high voltage isolation and the standard thermal and humidity cycling.

In other embodiments, such as for other CdTe PV modules, the TCO conductivity and the back contact conductivity are high enough that no grid lines are necessary; current flows perpendicular to the individual cell strips. However, buss lines may be utilized at the ends of the RTR-processed modules to collect the current for the junction box, which brings the current through the encapsulation and out of the panel.

Also, in certain embodiments, the RTR manufacturing line can include stations such as an RTR coating line with on-line chloride activation, followed by the monolithic (sub)module integration and cutting into modules. Also, the RTR manufacturing line can include the process of encapsulating the PV submodule to form a completed PV module.

While the invention has been described with reference to particular embodiments, it should be understood by those skilled in the art that various changes may be made and equivalents may be substituted for elements thereof without departing from the essential scope of the invention. In addition, many modifications may be made to adapt a particular situation or material to the teachings of the invention without departing from the essential scope thereof. Therefore, it is intended that the invention not be limited to the particular embodiments disclosed herein contemplated for carrying out this invention, but that the invention will include all embodiments falling within the scope of the claims. The publication and other material used herein to illuminate the invention or provide additional details respecting the practice of the invention, are incorporated by reference herein.

1.-41. (canceled)

42. A method of forming a photovoltaic cell comprising the steps of:
providing a semiconductor layer on a polymer substrate layer; and
exposing the semiconductor layer to a chloride activation process having a chlorine exposure cycle and a rapid thermal activation cycle, the rapid thermal activation cycle having a rate of temperature change causing a strain in the polymer substrate that is greater than a fracture strain limit of glass.

43. The method of claim 42, in which the chlorine exposure cycle includes CdCl₂ vapors.

44. The method of claim 43, in which the CdCl₂ vapors are provided in a carrier gas comprising one of dry air or a mixture of O₂ and an inert gas.

45. The method of claim 43, in which the CdCl₂ vapors are provided by a solution of CdCl₂ and a solvent.

46. The method of claim 42, in which the chlorine exposure cycle includes trichloromethane.

47. The method of claim 42, in which a transparent conductive oxide (TCO) layer is applied to the polymer substrate layer such that the TCO layer forms an electrical contact that is configured to allow light to pass therethrough to the active layers.

48. The method of claim 47, in which a highly resistive transparent (HRT) layer is applied to the TCO layer, the HRT layer configured to form a TCO/HRT bilayer providing at least one of an electrical isolation function and a chemical diffusion barrier function.

49. The method of claim 48, wherein an active layer is sputter deposited onto the TCO/HRT bilayer.

50. The method of claim 49, in which the active layer sputter deposition step is an RF magnetron sputter deposition step that deposits at least one of a CdTe layer and a CdS layer.

51. The method of claim 50, in which the chlorine exposure cycle is a CdCl₂ vapor exposed to one of the CdTe layer and the CdS layer.

52. The method of claim 42, in which the rapid thermal activation cycle includes one of a temperature exposure time in the range of 1 to 5 minutes and a temperature exposure range of about 350° C. to about 450° C.

53. The method of claim 49, in which a heating step provides a deposition temperature of about 250° C. prior to the sputter deposition of the TCO/HRT bilayer.

54. The method of claim 53, in which a CdTe layer and a CdS layer are sputter deposited onto the TCO/HRT bilayer followed by the chlorine exposure cycle having a cycle temperature of about 390° C. and including exposure of one of the CdTe and the CdS layers to saturated vapors of CdCl₂ and further including vacuum depositing a metal back contact, and providing a final heat treatment of about 150° C. in air.

55. The method of claim 42, in which the polymer substrate layer is a polyimide substrate that has a first optical transparency characteristic prior to the step of forming the semiconductor layer onto the polymer substrate layer, and wherein the rapid thermal activation cycle causes the polymer substrate layer to have a second optical transparency characteristic that is about 95% of the first optical transparency characteristic.

56. The method of claim 42, in which the photovoltaic cell is formed in a roll-to-roll manufacturing process.

57. A method of forming a photovoltaic cell comprising the steps of:
providing a semiconductor layer on a polymer substrate layer; and
exposing the semiconductor layer to a chloride activation process having a chlorine exposure cycle and a rapid thermal activation cycle, the rapid thermal activation cycle having a rate of temperature change greater than about 200° C. per minute.

58. A photovoltaic cell comprising:
a flexible polymer superstrate layer having a first optical transparency characteristic prior to a cell layer assembly process; and
at least one active semiconductor layer having been applied during the cell layer assembly process, the semiconductor layer having been exposed to a chlorine exposure cycle and a rapid thermal activation cycle such that the polymer-based superstrate layer takes on a second optical transparency characteristic that is about 95% of the first optical transparency characteristic.

59. The photovoltaic cell of claim 58, in which the polymer superstrate layer is a polyimide layer configured as a photovoltaic cell front window, the cell further including a TCO layer applied onto the flexible polymer superstrate layer, a CdS layer applied onto the TCO layer, and a CdTe layer applied onto the CdS layer, and a back contact layer.

60. The photovoltaic cell of claim 59, in which the TCO layer is a TCO/HRT bilayer.

61. The photovoltaic cell of claim 59, in which the CdTe layer is a p-doped CdTe layer, and the back contact layer includes a copper layer treated with one of gold and molybdenum.

62. A photovoltaic cell comprising:
a polyimide superstrate layer having a strain characteristic that is more compliant than a soda lime glass strain characteristic;
a bilayer applied onto the polyimide superstrate, the bilayer including a transparent conductive oxide (TCO) layer formed from an aluminum-doped zinc oxide material and a highly resistive transparent (HRT) layer formed from an undoped zinc oxide material;
one of a CdS and a CdTe layer deposited onto the bilayer and exposed to a CdCl₂ vapor and rapid thermal activation process having heating and cooling cycle rates exceeding the soda lime glass strain characteristic; and
a back contact layer.

63. The photovoltaic cell of claim 62, in which the polyimide substrate has an optical transparency characteristic, the optical transparency characteristic of the polyimide superstrate layer is substantially maintained after exposure to the CdCl₂ vapor and rapid thermal activation process.

64. The photovoltaic cell of claim 63, in which the optical transparency characteristic is based on transmitted light irradiance and is between 400 nanometers and 850 nanometers.

65. The photovoltaic cell of claim 64, in which the optical transparency characteristic is between 600 nanometers and 700 nanometers.

66. The photovoltaic cell of claim 62, in which the CdS and CdTe layers form an active semiconductor layer after exposure to the CdCl₂ vapor and rapid thermal activation process.

67. The photovoltaic cell of claim 66, in which the active semiconductor layer is a plurality of active semiconductor layers configured to define a plurality of cell sub-modules, the plurality of active semiconductor layers being electrically connected by scribes to form a series connection between the back contact layer of one sub-module and the front contact of another sub module.

68. A photovoltaic cell produced by the method of claim 42.

69. A photovoltaic cell comprising:
a polyimide superstrate layer;
a bilayer applied onto the polyimide superstrate layer, the bilayer including a transparent conductive oxide (TCO) layer formed from an aluminum-doped zinc oxide material and a highly resistive transparent (HRT) layer formed from an undoped zinc oxide material;
at least one of a CdS and a CdTe layer deposited onto the bilayer and exposed to a CdCl₂ vapor and rapid thermal activation process having heating and cooling cycle rates exceeding 200° C. per minute; and
a back contact layer.
